(19) United States
(12) Patent Application Publication
(10) Pub. No.: US 2026/0138162 A1
(43) Pub. Date: May 21, 2026

(54) SYSTEM AND METHOD FOR CLEANING A CHAMBER

(71) Applicant: Applied Materials, Inc., Santa Clara, CA (US)

(72) Inventors: Chang Ke, Santa Clara, CA (US); Peiyu Zhang, Santa Clara, CA (US); Changgong Wang, San Jose, CA (US); Xiaoxiong Yuan, Santa Clara, CA (US); Aviral Kedia, West Bengal (IN); Sangeeta Paul, Bangalore (IN); Anand Joy, Bangalore (IN)

(21) Appl. No.: 18/952,326

(22) Filed: Nov. 19, 2024

(51) Int. Cl. B08B 9/093; B08B 13/00; H01L 21/67

(52) U.S. Cl. CPC B08B 9/093; B08B 13/00; H10P 72/0402; B08B 2209/08

(57) ABSTRACT

Described herein are embodiments related to a chamber and method for cleaning herein including a dual gas line system. The chamber includes a first input line including a first outlet positioned within the chamber to output a first gas stream and a second input line including a second outlet positioned within the chamber to output a second gas stream. The first input gas line and the second input gas line are coaxial to each other, and the outlets directly face each other.

### TECHNICAL FIELD

Embodiments of the present disclosure relate generally to a chamber including a dual gas line to input a first gas stream and a second gas stream to the chamber, and a method for applying gas to the chamber through the dual gas line to control an angle of a gas curtain caused by an intersection of the gas streams.

### BACKGROUND

In the semiconductor industry, several chambers may be used when processing a substrate. For example, the chambers may include a load lock, processing chamber or a vacuum chamber. During the various manufacturing processes, the chambers are exposed to high temperatures, high energy plasma, a mixture of corrosive gases, high stress, and combinations thereof. These extreme conditions may erode and/or corrode chamber components causing particles to form within the chamber. The presence of particles within the chamber may cause a yield loss or chamber down time due to cleaning of the chamber.

To minimize down time, chambers may be cleaned through an in situ gas pump purge, which is generally inefficient and may not remove particles completely.

### SUMMARY

In an embodiment of the disclosure, a chamber is provided including a dual gas line to address the issues associated with conventional in situ gas pump purge systems. The chamber includes a first input gas line including a first outlet positioned within the chamber and configured to output a first gas stream. The chamber further includes a second input gas line including a second outlet positioned within the chamber and configured to output a second gas stream. The first input gas line and the second gas line may be coaxial to each other, and wherein the first outlet and the second outlet may directly face each other such that the first gas stream may be directed towards the second output and the second gas stream may be directed towards the first output. The chamber may also include a controller operatively coupled to the first input gas line and the second input gas line, wherein the controller may control a first flow rate of a first gas through the first input gas line and a second flow rate of a second gas through the second input gas line to control an angle of a gas curtain caused by an intersection of a first gas stream and the second gas stream.

In another embodiment of the disclosure, a method is provided. The method includes outputting a first gas stream through a first gas line including a first outlet at a first flow rate in a chamber. The method further includes outputting a second gas stream through a second gas line including a second outlet at a second flow rate in the chamber, wherein the first outlet and the second outlet may directly face each other such that the first gas stream may be directed towards the second output and the second gas stream may be directed towards the first output.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

The drawings, described below, are for illustrative purposes only and are not necessarily drawn to scale. The drawings are not intended to limit the scope of the disclosure in any way.

FIG. 1 illustrates a top-down view of an exemplary embodiment of a substrate manufacturing system, including a load lock system, and its placement among other processing chambers and equipment in a factory setting.

FIG. 2 illustrates a sectional view of one embodiment of a chamber including a dual gas line described herein.

FIGS. 3a-3b depicts exemplary flow paths of the gas streams using dual gas line according to certain embodiments.

FIG. 4 illustrates an embodiment of the dual gas line.

FIG. 5 is a flow chart illustrating a method of cleaning a chamber according to an embodiment.

FIG. 6 illustrates an embodiment of a diagrammatic representation of a computing device associated with an embodiment of the present disclosure.

### DETAILED DESCRIPTION OF EMBODIMENTS

Embodiments described herein are related to a chamber cleaning system including a dual gas line and a method of cleaning the chamber using the same. The dual gas line is designed so that there is independent control on each gas line to control the flow rate through each gas line. Further, the outlets of the respective gas lines are coaxial and face each other, which allows for more efficient cleaning of particles within the chamber. Moreover, by having the outlets face each other, a gas curtain may be generated by flowing gas streams from the two outlets towards each other. By adjusting the respective flow rates of the two gas streams, an angle of the gas curtain may be controlled. This angle allows for the full chamber surface to be cleaned by sweeping the gas curtain throughout the entire chamber, causing the gas curtain to blow on the entire internal surface of the chamber (or nearly the entire surface). The particles can be removed through an exhaust port and pump. Additionally, the flow rate through the respective input gas lines may be pulsed to create a turbulent gas flow throughout the chamber to increase the cleaning efficiency. In addition, the outline of the gas line, i.e. nozzle, may be designed to generate high flow velocity which may lead to a high cleaning efficiency, e.g. de Laval nozzle for high velocity flow generation. Conventional gas lines, which include a single output creating a fixed gas path, cause limited internal areas of a chamber to be contacted by gas flow and cleaned. Conventional gas lines in a chamber may also have low gas velocity, as the single outlet limits the flow rate and gas flow path. Therefore, the dual gas lines of the present disclosure improves the area within the chamber that may be cleaned, and may increase the gas velocity for more efficient cleaning.

Embodiments described herein are directed to a chamber including a dual gas line. The chamber may include a first input gas line including a first outlet positioned within the chamber and configured to output a first gas stream; and a second input gas line including a second outlet positioned within the chamber and configured to output a second gas stream. In some embodiments, the first input gas line and the second input gas line may be coaxial to each other, and the first outlet and the second outlet may directly face each other such that the first gas stream may be directed towards the second output and the second gas stream may be directed towards the first output. Without being bound by a theory, by having the respective gas streams be directed toward each other, a turbulent gas flow may be created and may increase the average gas velocity of the gas flowed into the chamber. In some embodiments, the chamber may further include a controller operatively coupled to the first input gas line and the second input gas line. The controller may control a first flow rate of a first gas through the first input gas line and a second flow rate of a second gas through the second input gas lien to control an angle of a gas curtain caused by an intersection of a first gas stream and the second gas stream.

In some embodiments, the controller may be configured to pulse the first flow rate and the second flow rate. In some embodiments, the controller may configured to periodically or continuously adjust a ratio of the first flow rate to the second flow rate to adjust an angle of the gas curtain.

In some embodiments, the first flow rate and the second flow rate may produce an average gas velocity of about 15 m/s to about 300 m/s. In some embodiments, the average gas velocity may be about 15 m/s to about 300 m/s, about 20 m/s to about 250 m/s, 25 m/s to about 200 m/s, about 20 m/s to about 300 m/s, about 30 m/s to about 150 m/s, about 40 m/s to about 100 m/s, or about 50 m/s to about 80 m/s. In some embodiments, the average gas velocity may be about 15 m/s, about 20 m/s, about 25 m/s, about 30 m/s, about 35 m/s, about 40 m/s, about 45 m/s, about 50 m/s, about 75 m/s, about 100 m/s, about 125 m/s, about 150 m/s, about 175 m/s, about 200 m/s, about 225 m/s, about 250 m/s, about 275 m/s, or about 300 m/s

In some embodiments, a ratio of the first flow rate and the second flow rate is 0 to 1. In some embodiments, a ratio of the first flow rate and the second flow rate is 0.1, 0.2, 0.3, 0.4, 0.5, 0.6, 0.7, 0.8, 0.9, or 1. Similarly, a ratio of the second flow rate to the first flow rate may be 0 to 1, or about 0.1, 0.2, 0.3, 0.4, 0.5, 0.6, 0.7, 0.8, 0.9, or 1. In embodiments, the flow ratio may be periodically or continuously adjusted to cause a gas curtain to sweep the interior of the chamber.

In some embodiments, the chamber may further include an outlet gas line and a pump coupled to the outlet gas line. In some embodiments, the gas curtain may cause particles on surfaces of the chamber to become airborne, and the pump may pump the particles out of the chamber though the outlet gas line.

In some embodiments, the chamber may further include at least one particle sensor to generate a measurement of particles (e.g., airborne particles that have become airborne by the gas curtain) in the chamber. In some embodiments, the at least one particle sensor may include a light scattering sensor, an impactor sensor, an aerosol electrometer, a mass spectrometer, a residual gas analyzer (RGA) sensor, a weight sensor, a surface acoustic wave (SAW) sensor, or a corona discharge sensor.

In some embodiments, the chamber may further include a computer subsystem (e.g., the controller) configured to process a measure of an amount of particles in the chamber from at least one particle sensor, and determine whether to adjust the first flow rate, the second flow rate, or a combination thereof based on the amount of particles. In some embodiments, the computer subsystem (e.g., controller) may determine whether to stop the first flow rate, the second flow rate, or a combination thereof based on the amount of particles, i.e. stopping the cleaning process.

In some embodiments, the gas of the chamber may include at least one of argon, nitrogen or air. In some embodiments, the chamber may include a load lock, a process chamber, or a vacuum chamber.

In some embodiments, a method is provided to perform a cleaning in the chamber. The method may include outputting a first gas stream through a first gas line including a first outlet positioned within a chamber; and outputting a second gas stream through a second gas line including a second outlet positioned within the chamber. In some embodiments, the first outlet and the second outlet may be coaxial and may directly face each other such that the first gas stream may be directed towards the second output and the second gas stream may be directed towards the first output.

In some embodiments, the method may further include controlling a first flow rate of a first gas through the first gas input line and second flow rate of a second gas through the second input gas line to control an angle of a gas curtain caused by an intersection of the first gas stream and the second gas stream. In some embodiments, the method may further include pulsing the output of the first gas stream and the output of the second gas stream.

In some embodiments, the method may further include measuring an amount of particles in the chamber using at least one particle sensor. In some embodiments, the method may further include processing the amount of particles via a computing subsystem to determine whether to adjust at least one of the first gas stream and the second gas stream.

In some embodiments, the method may further include adjusting at least one of the first gas stream and the second gas stream responsive to a determination to adjust a flow rate of the respective gas stream. In other embodiments, the method may further include determining whether to stop outputting the first gas stream and the second gas stream based on the amount of particles.

In some embodiments, the first gas stream and the second gas stream may have an average velocity higher than 300 m/s.

The components of the embodiments as generally described and illustrated in the figures herein can be arranged and designed in a wide variety of different configurations. Thus, the detailed description of various embodiments, as represented in the figures, is not intended to limit the scope of the present disclosure but is merely representative of various embodiments. While various aspects of the embodiments are presented in drawings, the drawings are not necessarily drawn to scale unless specifically indicated. The phrase “coupled to” is broad enough to refer to any suitable coupling or other form of interaction between two or more entities, including direct and/or indirect mechanical, fluidic and thermal interaction. Thus, two components may be coupled to each other even though they are not in direct contact with each other. The phrases “attached to” or “attached directly to” refer to interaction between two or more entities which are in direct contact with each other and/or are separated from each other only by a fastener of any suitable variety (e.g., mounting hardware or an adhesive). The phrase “fluid communication” is used in its ordinary sense, and is broad enough to refer to arrangements in which a fluid (e.g., a gas or a liquid) can flow from one element to another element when the elements are in fluid communication with each other.

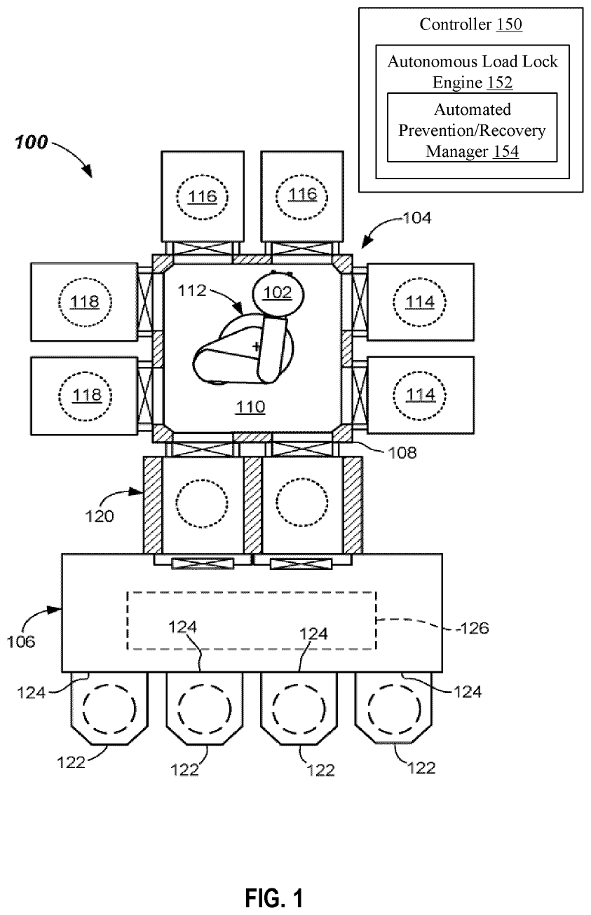

Referring now to the figures, FIG. 1 is a diagram of a cluster tool 100 (also referred to as a system, substrate processing system or manufacturing system) that is configured for substrate fabrication in accordance with at least some embodiments of the disclosure. In an exemplary embodiment, a manufacturing system (e.g., cluster tool 100) may comprise a processing portion 104, a transfer chamber 110, a load lock 120, a factory interface 106, and substrate carriers 122 or front opening unified pods (FOUPs). Processing portion 104 may comprise a plurality of process chambers 114, 116, and 118, wherein specific and controlled substrate manufacturing processes occur. Transfer chamber 110 may house a transfer robot (robot arm 112) comprising a substrate transfer mechanism, or end effector (substrate transfer mechanism and end effector will be used interchangeable moving forward in the disclosure) that may transport substrates 102. Transfer chamber 110 may be in transfer chamber housing 108. Load lock 120 may interface with both the processing portion 104 and the factory interface 106. Factory interface 106 may comprise a factory interface robot 126, for transferring substrates to and from the carriers 122 and the load lock 120. Factory interface may further comprise a plurality of load ports 124 for receiving carriers 122 carrying one or more substrates. Transfer chamber 110 is generally maintained at vacuum pressure levels, while factory interface 106 is generally maintained at atmospheric pressure.

In some embodiments, transfer chamber 110, process chambers 114, 116, and 118, and load lock 120 may be maintained at a vacuum level. The vacuum level for the transfer chamber 110 may range from about, e.g., 1 mTorr (or about 5 mT, 10 mT, 15 mT, 20 mT, 50 mT, 100 mT, etc.) to about 80 Torr (or about 0.5 Torr, 0.8 Torr, 1 Torr, 5 Torr, 20 Torr, 50 Torr, etc.). Other vacuum levels may be used.

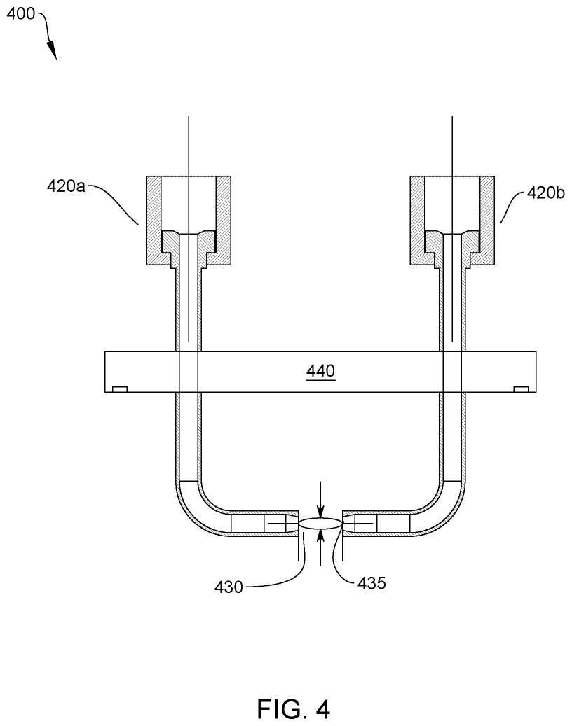

In some embodiments, transfer chamber 110, process chambers 114, 116 and 118, and/or load lock 120 may include a dual gas line as described herein, such as in FIG. 4.

The factory interface robot 126 is configured to transfer the substrate from the carriers (FOUPs) 122 to load locks 120 through load lock doors. The number of load locks can be more or less than two but for illustration purposes only, two load locks 120 are shown with each load lock having a door (e.g., a slit valve) to connect it to the factory interface 106 and a door to connect it to the transfer chamber 110. Load locks 120 may or may not be batch load locks (e.g., load locks that can hold a plurality of substrates at a time). In embodiments, the load locks are smart load locks capable of performing self-diagnosis and/or automated prevention and/or recovery.

The load locks 120, under the control of a controller 150, can be maintained at either an atmospheric pressure environment or a vacuum pressure environment, and serve as an intermediary or temporary holding space for a substrate that is being transferred to/from the transfer chamber 110. The transfer chamber includes robot arm 112 that is configured to transfer the substrate from the load locks 120 to one or more of the plurality of processing chambers 114, 116, 118 (also referred to as process chambers), or to one or more pass-through chambers (also referred to as vias), without vacuum break, i.e., while maintaining a vacuum pressure environment within the transfer chamber 110 and the plurality of processing chambers 114, 116, 118.

A door, e.g., a slit valve door, connects each respective load lock 120 to the transfer chamber 110. The plurality of processing chambers 114, 116, 118 are configured to perform one or more processes. Examples of processes that may be performed by one or more of the processing chambers 114, 116, 118 include cleaning processes (e.g., a pre-clean process that removes a surface oxide from a substrate), anneal processes, deposition processes (e.g., for deposition of a cap layer, a hard mask layer, a barrier layer, a bit line metal layer, a barrier metal layer, etc.), etch processes, and so on. Examples of deposition processes that may be performed by one or more of the process chambers include physical vapor deposition (PVD), chemical vapor deposition (CVD), atomic layer deposition (ALD), and so on. Examples of etch processes that may be performed by one or more of the process chambers include plasma etch processes.

Controller 150 (e.g., a tool and equipment controller, a tool cluster controller, etc.) may control various aspects of the cluster tool 100, e.g., gas pressure in the processing chambers, individual gas flows, spatial flow ratios, plasma power in various process chambers, temperature of various chamber components, radio frequency (RF) or electrical state of the processing chambers, and so on. The controller 150 may receive signals from and send commands to any of the components of the cluster tool 100, such as the robot arms 112, 126, process chambers 114, 116, 118, load locks 120, slit valve doors, and/or one or more sensors, and/or other processing components of the cluster tool 100. The controller 150 may thus control the initiation and cessation of processing, may adjust a deposition rate and/or target layer thickness, may adjust process temperatures, may adjust a type or mix of deposition composition, may adjust an etch rate, may initiate automated prevention and/or recovery processes on the load lock 120, and the like. The controller 150 may further receive and sensor measurement data (e.g., optical measurement data, vibration data, spectrographic data, particle detection data, temperature data, etc.) from various sensors and make decisions based on such measurement data.

In various embodiments, the controller 150 may be and/or include a computing device such as a personal computer, a server computer, a programmable logic controller (PLC), a microcontroller, and so on. The controller 150 may include (or be) one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. The controller 150 may include a data storage device (e.g., one or more disk drives and/or solid state drives), a main memory, a static memory, a network interface, and/or other components. The processing device of the controller 150 may execute instructions to perform any one or more of the methodologies and/or embodiments described herein. The instructions may be stored on a computer readable storage medium, which may include the main memory, static memory, secondary storage and/or processing device (during execution of the instructions). In some embodiments, controller 150 is a dedicated controller for load lock(s) 120.

In one embodiment, the controller 150 includes an autonomous load lock engine 152. The autonomous load lock engine 152 may be implemented in hardware, firmware, software, or a combination thereof. The autonomous load lock engine 152 may be configured to receive and process measurement data generated by one or more sensors of load locks 120 during and/or after cycling of substrates through the load locks. The sensor measurements may include temperature measurements, pressure measurements, particle measurements, spectrographic measurements, vibration measurements, accelerometer measurements, voltage measurements, current measurements, resistance measurements, time measurements, optical measurements (e.g., such as optical emission spectrometry measurements and/or reflectometry measurements), position measurements, humidity measurement, part health measurements, and/or other types of measurements. Some example measurements include a chamber pressure (e.g., which may be measured in mTorr), OES spectra measurements for one or more wavelengths or frequencies (e.g., for wavelengths of 3870 nm, 7035 nm, 775 nm, and so on), one or more substrate support/heater temperatures, one or more substrate temperatures, and so on. Some or all of these measurements may be combined to generate a feature vector that is input into a trained machine learning model of the autonomous tool engine 121.

The autonomous load lock engine 152 running on controller 150 may include one or more rules-based engines and/or trained machine learning models for controlling and/or making decisions for one or more load locks. The one or more trained machine learning models may have been trained to receive sensor measurements from and/or associated with a load lock 120 and to make a prediction, classification or determination about the load lock. Each of the trained machine learning models may be associated with a different decision-making process for a load lock in embodiments. For example, a trained machine learning model may be trained to process particle data from a particle sensor and determine whether or not a load lock is clean based on the particle data. Alternatively, one or a few trained machine learning models may be associated with multiple decision-making processes for a load lock in embodiments.

In one embodiment, one or more of the trained machine learning models is a regression model trained using regression. Examples of regression models are regression models trained using linear regression or Gaussian regression. A regression model predicts a value of Y given known values of X variables. The regression model may be trained using regression analysis, which may include interpolation and/or extrapolation. In one embodiment, parameters of the regression model are estimated using least squares. Alternatively, Bayesian linear regression, percentage regression, leas absolute deviations, nonparametric regression, scenario optimization and/or distance metric learning may be performed to train the regression model.

In one embodiment, one or more of the trained machine learning models are decision trees, random forests, support vector machines, or other types of machine learning models.

In one embodiment, one or more of the trained machine learning models is an artificial neural network (also referred to simply as a neural network). The artificial neural network may be, for example, a convolutional neural network (CNN) or a deep neural network. In one embodiment, processing logic performs supervised machine learning to train the neural network.

Artificial neural networks generally include a feature representation component with a classifier or regression layers that map features to a target output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs). The neural network may be a deep network with multiple hidden layers or a shallow network with zero or a few (e.g., 1-2) hidden layers. Deep learning is a class of machine learning algorithms that use a cascade of multiple layers of nonlinear processing units for feature extraction and transformation. Each successive layer uses the output from the previous layer as input. Neural networks may learn in a supervised (e.g., classification) and/or unsupervised (e.g., pattern analysis) manner. Some neural networks (e.g., such as deep neural networks) include a hierarchy of layers, where the different layers learn different levels of representations that correspond to different levels of abstraction. In deep learning, each level learns to transform its input data into a slightly more abstract and composite representation.

One of more of the trained machine learning models may be recurrent neural networks (RNNs). An RNN is a type of neural network that includes a memory to enable the neural network to capture temporal dependencies. An RNN is able to learn input-output mappings that depend on both a current input and past inputs. The RNN will address past and future measurements and make predictions based on this continuous measurement information. For example, sensor measurements may continually be taken during a process, and those sets of measurements may be input into the RNN sequentially. Current sensor measurements and prior sensor measurements may affect a current output of the trained machine learning model. One type of RNN that may be used is a long short term memory (LSTM) neural network.

Some trained machine learning models of an autonomous load lock engine 152 use all sensor measurements generated by a load lock. Some trained machine learning models of an autonomous load lock engine 152 use a subset of generated sensor measurements.

In one embodiment, autonomous load lock engine 152 includes an automated prevention and/or recovery manager 154. Automated prevention and/or recovery manager 154 may include one or more rules-based systems and/or one or more trained machine learning models that are trained to receive sensor measurements of a load lock and to output a decision as to whether or not a prevention or recovery action such as maintenance should be performed on the load lock.

Controller 150 may be operatively connected to a server (not shown). The server may be or include a computing device that operates as a factory floor server that interfaces with some or all tools in a fabrication facility. The server may perform training to generate the trained machine learning models, and may send the trained machine learning models to autonomous load lock engine 152 on controller 150. Alternatively, the machine learning models may be trained on controller 150.

Training of a neural network may be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset. In high-dimensional settings, such as large images, this generalization is achieved when a sufficiently large and diverse training dataset is made available.

A load lock chamber in a vacuum processing system is used to allow substrates, such as silicon wafers or other substrates, to be loaded and unloaded without disrupting the vacuum environment of a main process chamber or transfer chamber.

The substrate support of a load lock chamber typically refers to the structure or device that holds the substrate in place. It is designed to securely hold the substrate while ensuring that it can be moved into and out of the load lock chamber with ease and without damage. Some substrate supports are flat platforms or trays on which the substrate rests. These may be static or include mechanisms for rotation or other movement, such as vertical movement. Some substrate supports may also include clamping or other securement mechanisms to keep the substrate in place, particularly during any movements. In some embodiments, the substrate support has thermal control capabilities. For instance, the substrate support can be heated or cooled to heat or cool supported substrates and/or maintain the substrates at a particular temperature. Substrate supports may include embedded heating elements that apply resistance heating in one or more zones, may include optical heating, and so on. Substrate supports may additionally or alternatively include cooling mechanism, such as channels through which a coolant is flowed to provide liquid cooling of supported substrates.

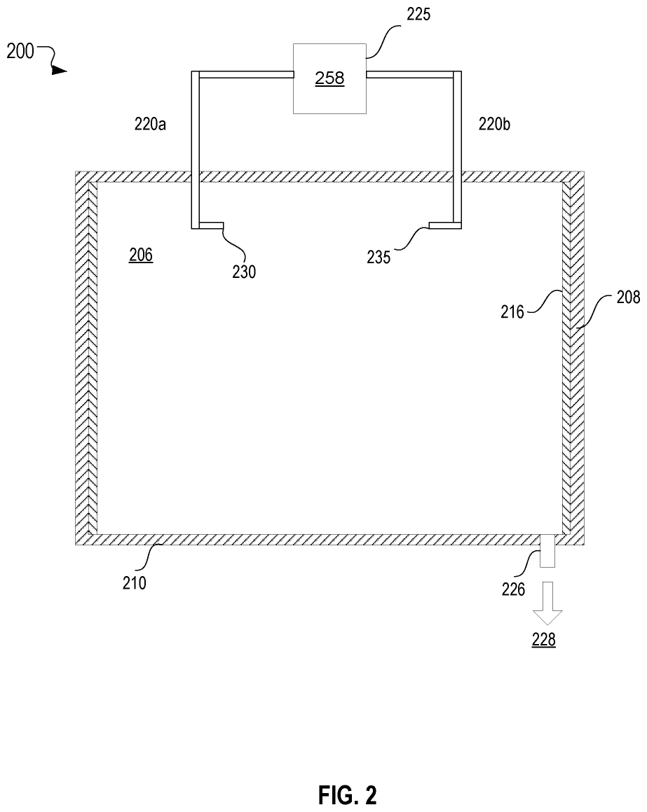

Referring to FIG. 2, a sectional view of a chamber 200 (e.g., a load lock chamber) having one or more chamber components in accordance with embodiments of the present disclosure.

In one embodiment, the chamber 200 includes a chamber body and a dual gas line system 225 that enclose an interior volume 206. The dual gas line system 225 includes a gas panel 258 and gas input lines 220a, 220b. The dual gas line system 225 may be supported on side walls 208 of the chamber body and/or on a top portion of the chamber body. The gas panel 258 may be coupled to the chamber 200 to provide purge gases (e.g., air, argon, nitrogen, etc.) to the interior volume 206 through the gas input lines 220a, 220b. Each gas input line 220a, 220b includes an output, 230, 235, respectively. The outputs 230 and 235 may be configured to directly face each other such that a first gas stream from a gas input line 220a may be directed towards the second output 235, and a second gas stream from a gas input line 220b may be directed towards the first output 230. In some embodiments, the outputs 230 and 235 may be coaxial, or may be slightly off center. In some embodiments, the gas input lines 220a, 220b may be coaxial to each other. As understood herein, “coaxial” refers to being along the same axis.

The dual gas line system 225 may be used to clean the chamber 200 to remove particles that may form while running processes in the chamber 200, moving substrates through the chamber, etc. The gas may be flowed through the system 225 to the interior volume 206 of the chamber, which causes particles to dislodge from surfaces of the interior of the chamber, to become airborne, and to move into the interior volume 206. The particles may then be pumped out using a pump system 228.

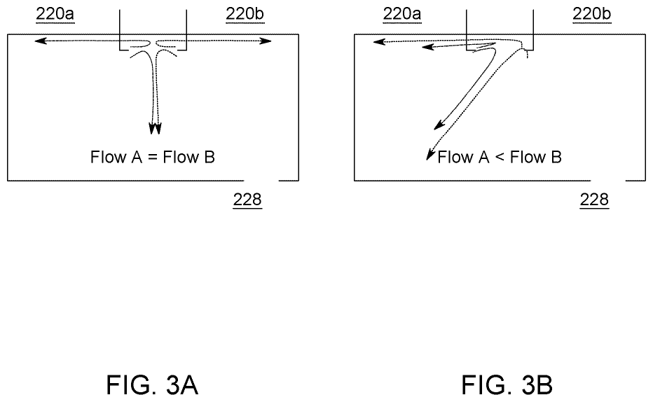

The gas line system 225 may further include a controller (not pictured) coupled to a first input gas line 220a and the second input gas line 220b. The controller may control a first flow rate of a first gas through the first input gas line 220a and a second flow rate of a second gas through the second input gas line 220b to control an angle of a gas curtain caused by an intersection of a first gas stream and the second gas stream. Examples of the gas streams are shown in FIGS. 3A and 3B. In FIG. 3A, the flow rate of the first gas line 220a and second gas line 220b are equal to the other. When the flow rates of the gases through the input gas lines are the same flow rate, then the gas flow may create a turbulent air flow space near the outputs that causes a gas curtain that is approximately vertical and the points downward (e.g., at approximately 90 degrees). By changing the ratio of the first flow rate through the first gas line 220a and the second flow rate through the second gas line 220b, the angle of the gas curtain may change. For example, in FIG. 3B, the flow rate of the first gas line 220a is less than the flow rate of the second gas line 220b. In this embodiment, the gas is forced to one side of the process chamber (e.g., towards a side of the chamber on which the first gas line 220a is placed). By decreasing the ratio of the first flow rate of the first gas line 220a vs. the second flow of the second gas line 220b, the angle of the gas curtain may be changed. If the first flow rate is reduced to zero (end the second flow rate is not zero), then the curtain may be horizontal towards the direction of the first gas line 220a. If the second flow rate is reduced to zero (and the first flow rate is not zero), then the curtain may be horizontal towards the direction of the second gas line 220b. Thus, the gas curtain may change its angle, sweeping the interior of the chamber and causing any potential void areas to be reached, when compared to a traditional gas line system. In some embodiments, the flow rate of the first gas line 220a and the flow rate of the second gas line 220b may be pulsed such that the gas may be angled to clean each side of the chamber.

Referring back to FIG. 2, the chamber body may be fabricated from aluminum, stainless steel, or other suitable material. The chamber body generally includes sidewalls 208 and a bottom 210.

An exhaust port/outlet gas line 226 may be defined in the chamber body and may couple the interior volume 206 to a pump system 228. The pump system 228 may include one or more pumps and throttle valves utilized to evacuate and regulate the pressure of the interior volume 206 of the chamber 200. In some embodiments, the pump system 228 may be coupled to the outlet gas line 226. In some embodiments, the gas curtain that is produced within the chamber as described herein may cause particles on surfaces of the chamber to become airborne and the pump may pump the particles out of the chamber through the exhaust port/outlet gas line 226.

In some embodiments, at least one particle sensor (not pictured) may be included in the chamber. The at least one particle sensor may generate a measurement of particles in the chamber. In some embodiments, the at least one particle sensor may include a light scattering sensor, an impactor sensor, an aerosol electrometer, a mass spectrometer, a residual gas analyzer (RGA) sensor, a weight sensor, a surface acoustic wave (SAW) sensor, or a corona discharge sensor. In some embodiments, the at least one particle sensor may be a corona discharge sensor. A corona discharge sensor (often referred to as a corona discharge ionization detector) in combination with an electrometer can be used for particle detection, such as for air quality monitoring and in the detection of aerosol particles. A corona discharge is a process by which a current flows from an electrode with a high potential into a neutral fluid (usually air) by ionizing that fluid and creating a region of plasma around the electrode. The electrode is usually a thin wire with a high voltage applied to it. The high electric field near the wire causes ionization and a flow of current through the air. As particles pass through the corona discharge region, they become ionized or charged (e.g., they gain or lose electrons, thereby acquiring a net positive or negative charge). After the particles are charged, they move towards a collection electrode under the influence of an electric field. This collection electrode is connected to an electrometer.

An electrometer is a highly sensitive measuring instrument that can measure electric charge or electrical potential difference. When the charged particles hit the collection electrode, they cause a small current to flow, which is measured by the electrometer. By measuring the charge collected over time, it is possible to infer the number of particles that have passed through the detector. This is because each particle carries a certain amount of charge, so by measuring the total charge collected, and knowing the charge per particle, one can calculate the total number of particles. Additionally, larger particles tend to carry more charge, so it is also possible to make determinations about the size distribution of the particles. This makes it possible to count and sometimes size particles in a gas or air sample. These measurements can then be used to determine when to adjust the flow rates of the gas stream or to stop the cleaning process.

In some embodiments, a controller (not pictured) may be coupled to the first input gas line 220a and the second input gas line 220b. The controller may control a first flow rate of the gas through the first input gas line 220a and a second flow rate of a second gas through the second input gas line 220b. As discussed above, this may control an angle of a gas curtain caused by an intersection of a first gas stream and the second gas stream. In some embodiments, the controller may be configured to pulse the first flow rate and the second flow rate as described in relation to FIGS. 3A and 3B. In some embodiments, the controller may be configured to periodically or continuously adjust a ratio of the first flow rate to the second flow rate to adjust an angle of the gas curtain. In some embodiments, the first flow rate and the second flow rate produce an average gas velocity of about 15 m/s to about 50 m/s, about 20 m/s to about 45 m/s, about 25 m/s to about 40 m/s, or about 30 m/s to about 35 m/s. In some embodiments, the average gas velocity may be at least about 10 m/s, at least about 15 m/s, at least about 20 m/s, at least about 25 m/s, at least about 30 m/s, at least about 35 m/s, or at least about 40 m/s. In some embodiments, the first gas stream and the second gas stream each have an average gas velocity higher than about 2m/s, higher than about 5 m/s, higher than about 10 m/s, higher than about 20 m/s, higher than about 50 m/s, higher than about 75 m/s, higher than about 100 m/s, higher than about 125 m/s, higher than about 150 m/s, higher than about 175 m/s, higher than about 200 m/s, higher than about 225 m/s, higher than about 250 m/s, higher than about 275 m/s, or higher than about 300 m/s. In some embodiments, a ratio of the first flow rate to the second flow rate is varied between 0 to 1 and the ratio of the second flow rate to the first flow rate is varied between 0 to 1.

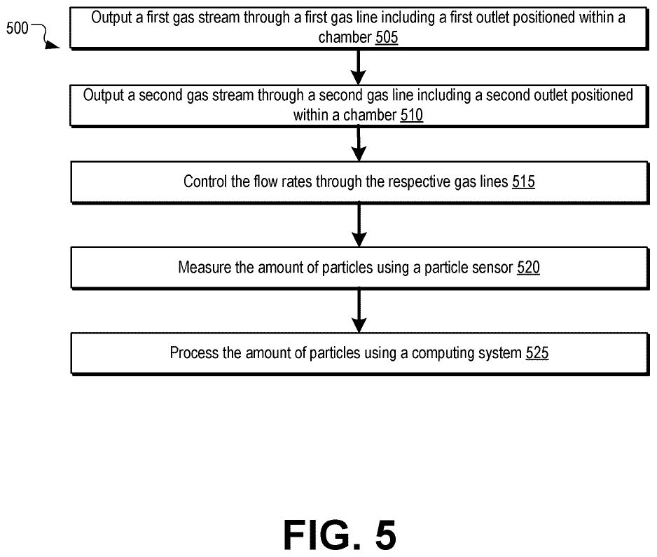

In some embodiments, the controller or some other computer subsystem is configured to process a measurement of an amount of particles in the chamber from the at least one particle sensor and determine whether to adjust the first flow rate, the second flow rate, or a combination thereof based on the amount of particles. In some embodiments, a particle sensor may be placed on each side of the processing chamber. Therefore, the flow rates may be adjusted depending on measurements of particles from a plurality of locations. The method will be described in more detail with reference to FIG. 5.

Referring to FIG. 4, a dual gas line system 400 according to an embodiment is shown. The dual gas line system 400 may include a first input gas line 420a including an outlet 430, and a second input gas line 420b and an outlet 435. As shown in FIG. 4, the first input gas line 420a and the second input gas line 420b are coaxial to each other. The first input gas line 420a and the second input gas line 420 b may be about 40 mm to about 200 mm apart, about 50 mm to about 190 mm, about 60 mm to about 180 mm, about 70 mm to about 170 mm, about 80 mm to about 160 mm, about 90 mm to about 150 mm, or about 100 mm to about 140 mm apart. The outlet 430 and outlet 435 may directly face each other such that the first gas stream from the first input gas line 420a may be directed towards the second output and the second gas stream from the second input gas line 420 b. In some embodiments, the outlets 430, 435 may be spaced about 10 mm apart. In some embodiments, the outlets 430, 435 may be about 5 mm to about 30 mm apart, about 10 mm to about 25 mm, or about 15 mm to about 20 mm. In some embodiments, the outlet 430, 435 may have a variety of different nozzles. In some embodiments, the nozzle of the outlets 430, 435, may be designed to have a concave nozzle, or may be a cylindrical nozzle. The dual gas line system 400 may be attached to the top of a chamber 440. The chamber may be a vacuum chamber, a load lock, or a processing chamber. The outlet of the gas lines may be designed to enhance gas flow velocity, e.g. de Laval (converging diverging type nozzle), which may improve the cleaning efficiency. As understand by one of skill in the art, a de Laval nozzle refers to a tube which is pinched in the middle forming an asymmetric hourglass shape.

In some embodiments, the gas that may be flowed through the chamber is any gas suitable to purge the chamber. In some embodiments, the gas may be argon, nitrogen, air or a combination thereof.

In some embodiments, the method for cleaning the chamber may be performed as purge clean cycles, which may be repeated any number of times and in an automated fashion that does not involve opening up the chamber to an exterior environment. In embodiments, purge clean cycles may be performed while no substrates are disposed within the chamber or while a test wafer is disposed within the chamber.

Referring to FIG. 5, a flow chart illustrating a method for cleaning a chamber 500 according to an embodiment is provided. In block 505, a first gas stream is outputted through a first gas line including a first outlet positioned within a chamber as shown in FIG. 2. In block 510, a second gas stream is outputted through a second gas line including a second outlet positioned within the chamber.

In block 515, the flow rates of the first gas stream and the second gas stream are controlled to control an angle of a gas curtain caused by an intersection of the first gas stream and the second gas stream. In some embodiments, the outputting of the first gas stream and the second gas stream may be pulsed into the chamber. In some embodiments, the output of the first gas stream and the second gas stream may occur simultaneously. In some embodiments, the outputting may be adjusted by adjusting the flow rate of the first gas stream and/or the flow rate of the second gas stream.

In block 520, the amount of particles is measured using the at least one particle sensor as described herein. After measuring the amount of particles, a computer subsystem (e.g., controller) may process the amount of particles in block 525. The processing may include determining whether to adjust at least one of the first gas stream and the second gas stream. The adjustment may include adjusting the flow rates of the first gas stream and/or the second gas stream, pulsing conditions, or stopping the flow from either gas stream or both streams to end the cleaning process.

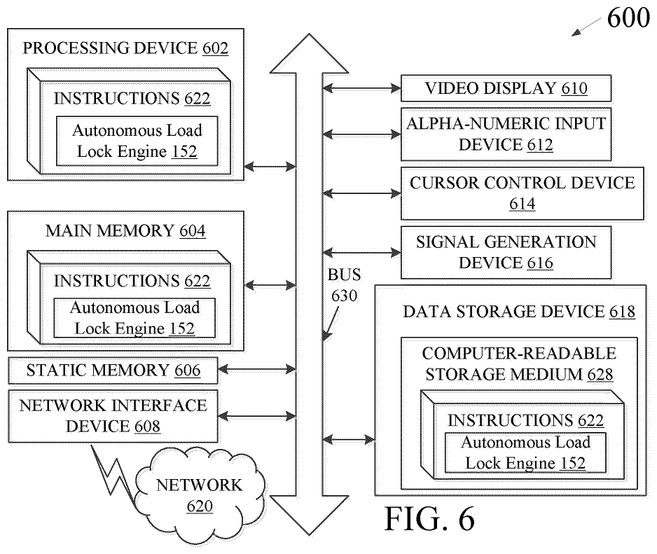

FIG. 6 illustrates a diagrammatic representation of a machine in the example form of a computing device 600 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, the computing device 600 may correspond to a controller for a tool cluster and/or load lock of a substrate processing system. For example, computing device 600 may correspond to controller 150 of FIG. 1.

The example computing device 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), hard disk (magnetic storage) etc.), and a secondary memory (e.g., a data storage device 618), which communicate with each other via a bus 630.

Processing device 602 represents one or more general-purpose processors such as a microprocessor, central processing unit, or the like. More particularly, the processing device 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 602 may also be one or more special-purpose processing devices such as an application specific integrated circuit (ASIC), a field programmable gate array (FPGA), a digital signal processor (DSP), network processor, or the like. Processing device 602 is configured to execute the processing logic (instructions 622) for performing the operations and steps discussed herein.

The computing device 600 may further include a network interface device 608. The computing device 600 also may include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 616 (e.g., a speaker).

The data storage device 618 may include a machine-readable storage medium (or more specifically a computer-readable storage medium) 628 on which is stored one or more sets of instructions 622 embodying any one or more of the methodologies or functions described herein. The instructions 622 may also reside, completely or at least partially, within the main memory 604 and/or within the processing device 602 during execution thereof by the computing device 600, the main memory 604 and the processing device 602 also constituting computer-readable storage media.

The computer-readable storage medium 628 may also be used to store an autonomous load lock engine 152, and/or a software library containing methods that call an autonomous load lock engine 152. While the computer-readable storage medium 628 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies described herein. The term “computer-readable storage medium” shall accordingly be taken to include, but not be limited to, non-transitory computer readable media such as solid-state memories, and optical and magnetic media.

The modules, components and other features described herein (for example in relation to FIGS. 1-2) can be implemented as discrete hardware components or integrated in the functionality of hardware components such as ASICS, FPGAs, DSPs or similar devices. In addition, the modules can be implemented as firmware or functional circuitry within hardware devices. Further, the modules can be implemented in any combination of hardware devices and software components, or only in software.

Some portions of the detailed description have been presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a target result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving”, “identifying”, “determining”, “selecting”, “providing”, “storing”, or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the present invention also relate to an apparatus for performing the operations herein. This apparatus may be specially constructed for the discussed purposes, or it may comprise a general purpose computer system selectively programmed by a computer program stored in the computer system. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A chamber comprising:
a first input gas line comprising a first outlet position within the chamber and configured to output a first gas stream;
a second input gas line comprising a second outlet positioned within the chamber and configured to output a second gas stream, wherein the first input gas line and the second input gas line are coaxial to each other, and wherein the first outlet and the second outlet directly face each other such that the first gas stream is directed towards the second output and the second gas stream is directed towards the first output; and;
a controller operatively couples to the first input gas line and the second input gas line, wherein the controller controls a first flow rate of a first gas through the first gas input line and a second flow rate of a second gas through the second input gas line to control an angle of a gas curtain caused by an intersection of a first gas stream and the second gas stream.

2. The chamber of claim 1, wherein the controller is configured to pulse the first flow rate and the second flow rate.

3. The chamber of claim 1, wherein the controller is configured to periodically or continuously adjust a ratio of the first flow rate to the second flow rate to adjust an angle of the gas curtain.

4. The chamber of claim 1, wherein the first flow rate and the second flow rate produce an average gas velocity of about 15 m/s to about 300 m/s.

5. The chamber of claim 1, wherein a ratio of the first flow rate and the second flow rate is 0 to 1.

6. The chamber of claim 1, further comprising:
an outlet gas line; and
a pump coupled to the outlet gas line, wherein the gas curtain is to cause particles on surfaces of the chamber to become airborne, and wherein the pump is to pump the particles out of the chamber through the outlet gas line.

7. The chamber of claim 1, wherein at least one of the first outlet and the second outlet comprise a de Laval nozzle.

8. The chamber of claim 1, further comprising at least one particle sensor to generate a measurement of particles in the chamber.

9. The chamber of claim 1, wherein the controller is further configured to:
process a measurement of an amount of particles in the chamber from at least one particle sensor; and
determine whether to adjust the first flow rate, the second flow rate, or a combination thereof based on the amount of particles.

10. The chamber of claim 1, wherein the controller is further configured to:
process a measurement of an amount of particles in the chamber from at least one particle sensor; and
determine when to stop applying the first gas and the second gas based on the amount of particles.

11. The chamber of claim 1, wherein the first gas or the second gas comprises at least one of argon, nitrogen or air.

12. The chamber of claim 1, wherein the chamber is a load lock chamber.

13. A method comprising:
outputting a first gas stream through a first gas line comprising a first outlet positioned within a chamber; and
outputting a second gas stream through a second gas line comprising a second outlet positioned within the chamber, wherein the first outlet and the second outlet are coaxial and directly face each other such that the first gas stream is directed towards the second output and the second gas stream is directed towards the first output; and
controlling a first flow rate of a first gas through the first gas input line and a second flow rate of a second gas through the second input gas line to control an angle of a gas curtain caused by an intersection of the first gas stream and the second gas stream.

14. The method of claim 13, wherein a ratio of the first gas to the second gas is from 0 to 1.

15. The method of claim 13, further comprising pulsing the output of the first gas stream and the output of the second gas stream.

16. The method of claim 13, further comprising measuring an amount of particles in the chamber using at least one particle sensor.

17. The method of claim 16, further comprising processing the amount of particles to determine whether to adjust at least one of the first gas stream and the second gas stream.

18. The method of claim 17, further comprising adjusting at least one of the first gas stream and the second gas stream responsive to a determination to adjust a flow rate of the respective gas stream.

19. The method of claim 17, further comprising determining whether to stop outputting the first gas stream and the second gas stream based on the amount of particles.

20. The method of claim 13, wherein the first gas stream and the second gas stream have an average velocity higher than 2 m/s.
